(19) United States
(12) Patent Application Publication
(10) Pub. No.: US 2007/0084597 A1
(43) Pub. Date: Apr. 19, 2007

(54) Control device of an air conditioning device of a motor vehicle and method for activating an air conditioning device

(75) Inventor: Thomas Heck, Mainz-Laubenheim (DE)

Correspondence Address: COHEN, PONTANI, LIEBERMAN & PAVANE, 551 FIFTH AVENUE, SUITE 1210, NEW YORK, NY, 10176, US

(73) Assignee: Siemens Aktiengesellschaft

(21) Appl. No.: 11/545,871

(22) Filed: Oct. 11, 2006

(30) Foreign Application Priority Data
Oct. 12, 2005 (DE) 10 2005 049 313.0

(51) Int. Cl. H01L 23/467; G05D 23/00

(52) U.S. Cl. 165/296; 165/121

(57) ABSTRACT

A control device of an air conditioning device of a motor vehicle has a fan, a control unit for activating the fan, and a suction connection of the fan arranged in the vicinity of electronic components generating heat. The electronic components are arranged upstream, relative to the flow of air toward the fan, of the suction connection of the fan. When the fan is switched on, the air surrounding the electronic components is extracted and therefore the heat generated by the electronic components is dissipated. An electric motor of the fan is activated by the control unit as a function of the heat generation of the electronic components.

### BACKGROUND OF THE INVENTION

The invention relates to a control device of an air conditioning device of a motor vehicle, with a control unit for activating a fan. Furthermore, the invention relates to a method for activating an air conditioning device, which has a fan, of a motor vehicle as a function of a temperature of electronic components to be cooled.

A control device of this type is known, for example, from DE 41 36 207 C1. In this device, electronic units arranged in side recesses which are partitioned off from the driver's compartment of the motor vehicle are supplied with air via a heat exchanger of a cooling or heating system. This air emerges again from the side recesses and passes into the driver's compartment. However, this design requires a complicated conduction of the air. Furthermore, electronic units arranged in the wind shadow of the air flow generated by the cooling or heating system are only inadequately cooled.

Furthermore, DE 198 04 698 A1 discloses a motor vehicle with an air conditioning system, in which a partial air flow sucked up by the fan is guided along electronic components. Another partial air flow is sucked up by the fan from the interior of the motor vehicle. However, this requires a complicated means of controlling the partial air flows.

### SUMMARY OF THE INVENTION

It is an object of the present invention to develop a control device of the type mentioned at the beginning in such a manner that it is of particularly simple construction and permits reliable dissipation of heat from electronic components arranged in the motor vehicle. Furthermore, a method for activating an air conditioning device having a fan is to be provided, said method permitting heat to be reliably dissipated from the electronic components with particularly little outlay.

According to a preferred embodiment of the invention, the control device of an air conditioning device of a motor vehicle comprises a fan, a control unit for activating the fan, and a suction connection of the fan arranged in the vicinity of electronic components generating heat.

According to this design, the air surrounding the electronic components is extracted and, for example, conveyed into the interior of the motor vehicle. The heat generated by the electronic components is therefore also extracted by the fan. The subsequent air flow after this process therefore cools the electronic components. Accordingly, wind shadows produced by the arrangement of the electronic components are largely avoided. The control device according to the invention does not require any means for dividing partial air flows and is therefore of particularly simple construction.

Heat generated by the electronic components is dissipated in a simple manner, according to an embodiment of the invention, if the control unit is connected to a temperature sensor arranged on the electronic components.

The use of a temperature sensor can be avoided, according to another embodiment of the invention, if the control unit is connected to a device for detecting a power consumption of the electronic components. Since the power consumption is a measure of the heat generated by the electronic components and can be detected with particularly little outlay, the fan can be activated if the power consumption of the electronic components exceeds a predetermined amount.

According to another embodiment of the invention, the dissipation of heat from the electronic components requires a particularly low structural outlay if the control unit has an intermittent circuit for the fan.

Heat from electronic components arranged at different locations in the motor vehicle can be dissipated in a simple manner according to another embodiment of the invention, if the fan is part of an air conditioning system, and if the air conditioning system can be activated together with the fan by the control unit.

The dirtying of the electronic components by air drawn from outside the motor vehicle can be avoided in a simple manner, according to another embodiment of the invention, if the electronic components are arranged in a circulating-air connection upstream, relative to an air flow from the circulating-air connection toward the fan, of a flap of the air conditioning system, which flap is switchable between the circulating-air connection and a fresh-air connection. The heat from the electronic components can therefore be dissipated while air flows afterwards from the interior of the motor vehicle to the electronic components.

The method for activating an air conditioning device, which has a fan, of a motor vehicle as a function of a temperature of electronic components to be cooled, comprises the steps of detecting the temperature of the electronic components directly or indirectly via the power consumption of the electronic components, and extracting air surrounding the electronic components with the fan, if the temperature of the electronic components is above a designated temperature. This method permits heat to be reliably dissipated from the electronic components with particularly little outlay.

According to this method, the heat generated by the electronic components is extracted with the air surrounding the electronic components as soon as a designated temperature of the electronic components is exceeded. The temperature of the electronic components can be detected indirectly or directly in a particularly simple manner. At the start of the method, the flap is preferably switched into a circulating-air position, so that air from the interior of the motor vehicle replaces the air extracted at the electronic components by the fan.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention permits numerous embodiments. To further clarify its basic principle, one of these is illustrated in the drawings and is described below.

FIG. 1 is a schematic diagram of a control device according to the invention; and

FIG. 2 is a diagrammatic flow diagram of a method for operating the control device according to the invention.

### DETAILED DESCRIPTION OF THE PRESENTLY PREFERRED EMBODIMENTS

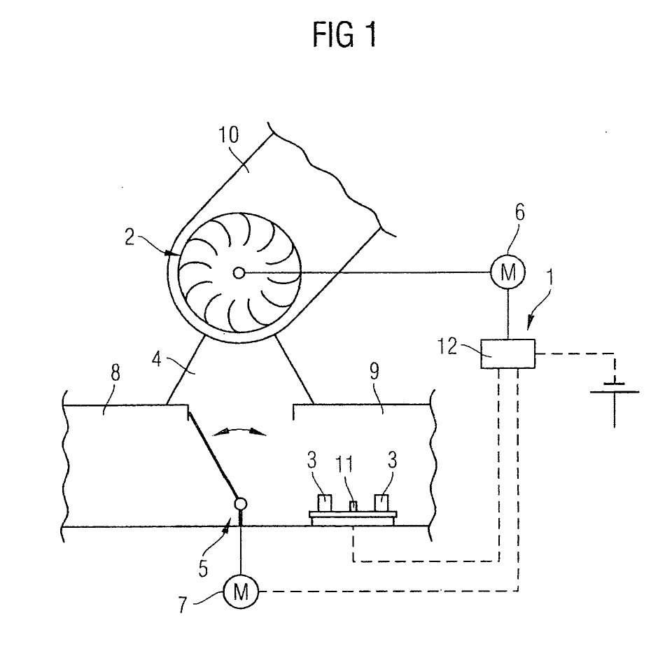

FIG. 1 shows, a control device 1 of a motor vehicle comprising a fan 2 arranged in a dashboard, and electronic components 3 generating heat. The electronic components 3 are arranged in a suction connection 4 of the fan 2 directly behind a switchable flap 5. The fan 2 and the flap 5 can be activated in each case by an electric motor 6, 7. The flap 5 is movable to connect the suction connection 4 of the fan 2 either to a fresh-air connection 8 or to a circulating-air connection 9. Air can be sucked up from outside the motor vehicle via the fresh-air connection 8 while the circulating-air connection 9 sucks up air from the interior of the motor vehicle. Irrespective of the position of the flap 5, the fan 2 conveys the sucked-up air via a ventilation duct 10 to ventilation slots (not illustrated) in the interior of the motor vehicle. The electric motors 6, 7 and a device 11, arranged between the electronic components 3, for detecting the heat generation of the electronic components 3, are connected to the control unit 12. The control unit 12 activates the electric motors 6, 7 as a function of the values provided by the device 11 for detecting the heat generation of the electronic components 3. The device 11 for detecting the heat generation may be a temperature sensor or a device detecting the power consumption of the electronic components 3.

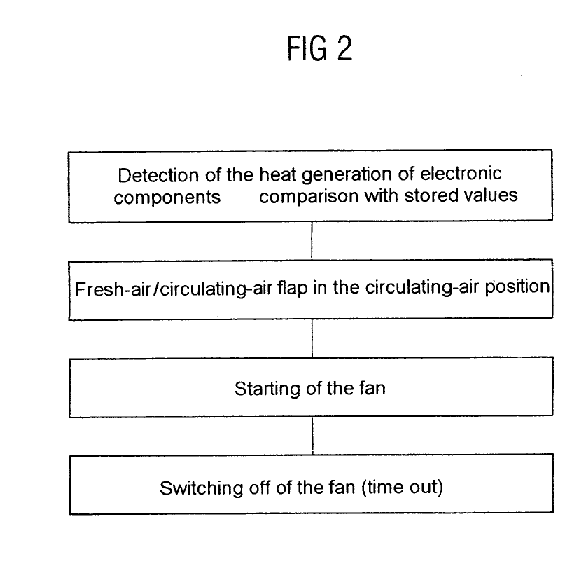

The method for operating the control device 1 is illustrated in a signal flow diagram in FIG. 2. First of all, the heat generation of the electronic components 3 is detected. The detected heat generation is compared with stored values. If the heat generation is above a designated value, the flap 5 is moved by activation of the corresponding electric motor 7 into the circulating-air position illustrated in FIG. 1 or is left in this position. Subsequently, the fan 2 is started and is switched off again after a designated period of time.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A control device of an air conditioning device of a motor vehicle, comprising:
a fan;
a control unit for activating the fan;
electronic components generating heat; and
a suction connection of the fan arranged in a vicinity of the electronic components, the fan being activatable for generating a flow of air toward the fan from the vicinity of the electronic components to the fan to facilitate the dissipation of heat generated by the electronic components.

2. The control device of claim 1, further comprising a temperature sensor arranged on the electronic components, the control unit being connected to the temperature sensor.

3. The control device of claim 1, further comprising a device for detecting a power consumption of the electronic components, the control unit being connected to the device for detecting the power consumption of the electronic components.

4. The control device of claim 1, wherein the control unit has an intermittent circuit for intermittent activation of the fan.

5. The control device of claim 1, wherein the fan is part of the air conditioning system, and the control unit is designed to activate the air conditioning system together with the fan.

6. The control device of claim 1, further comprising a flap of the air conditioning device for switching between a fresh-air connection and a circulating-air connection, the circulating-air connection being arranged upstream of the flap relative to a flow of air from the circulating-air connection toward the fan, and the electronics components being arranged in the circulating air connection.

7. A method for activating an air conditioning device of a motor vehicle having a fan as a function of a temperature of electronic components to be cooled, comprising the steps of:
detecting the temperature of the electronic components directly or indirectly via the power consumption of the electronic components; and
extracting air surrounding the electronic components with the fan by activating the fan or maintaining activation of the fan, if the temperature of the electronic components is above a designated temperature.
